(19) United States
(12) Patent Application Publication
(10) Pub. No.: US 2026/0123142 A1
(43) Pub. Date: Apr. 30, 2026

(54) DISPLAY PANEL AND METHOD FOR MANUFACTURING SAME

(71) Applicant: HKC CORPORATION LIMITED, SHENZHEN (CN)

(72) Inventors: Rong ZHANG, SHENZHEN (CN); Haijiang YUAN, SHENZHEN (CN)

(73) Assignee: HKC CORPORATION LIMITED, SHENZHEN (CN)

(21) Appl. No.: 19/356,131

(22) Filed: Oct. 12, 2025

(30) Foreign Application Priority Data
Oct. 31, 2024 (CN) 202411550650.3

(51) Int. Cl. H10H 29/49; H10H 20/01; H10H 20/83; H10H 20/852; H10H 29/01; H10H 29/03; H10H 29/80

(52) U.S. Cl. CPC H10H 29/49; H10H 20/032; H10H 20/0362; H10H 20/83; H10H 20/852; H10H 29/012; H10H 29/03; H10H 29/962

(57) ABSTRACT

The present application provides a display panel and a method for manufacturing the same. The display panel includes: a driving substrate including a first voltage line and a second voltage line; a plurality of stacked light-emitting unit modules arranged at intervals and arranged on a side of the driving substrate, each of the plurality of stacked light-emitting unit modules including a first light-emitting unit and a second light-emitting unit stacked and correspondingly arranged, where the first light-emitting unit includes a first light-emitting element, a first connection electrode, and a second connection electrode, the first connection electrode and the second connection electrode are arranged at intervals, the first connection electrode and the second connection electrode correspond one-to-one with the first voltage line and the second voltage line but are not all electrically connected.

### CROSS-REFERENCE TO RELATED APPLICATIONS

The present application claims priority to Chinese Patent Application No. 202411550650.3, entitled “DISPLAY PANEL AND METHOD FOR MANUFACTURING SAME”, filed on Oct. 31, 2024, which is herein incorporated by reference in its entirety.

### TECHNICAL FIELD

The present disclosure relates to the technical field of displays, in particular, to a display panel and a method for manufacturing the same.

### BACKGROUND

Micro light-emitting diode (Micro LED) is an emerging display technology and is considered one of the strong contenders for next-generation display technologies. With advantages such as high brightness, high contrast, low power consumption, fast response time, long service life, high reliability and the like, Micro LED technology has broad application prospects in fields including high-end displays, wearable devices, augmented reality (AR) and virtual reality (VR) devices, as well as outdoor billboards, etc.

However, in the related art, the mass transfer technology of Micro LED display panels has a relatively low yield, and there exists a problem that defective pixels in Micro LED display panels are difficult to repair. Moreover, the repair of defective pixels tends to affect the resolution of the display panel.

### SUMMARY

A first technical solution of the present disclosure is to provide a display panel, including: a driving substrate, including a first voltage line and a second voltage line; wherein one of the first voltage line and the second voltage line is a positive power voltage line, and an other is a ground voltage line; and a plurality of stacked light-emitting unit modules arranged at intervals and arranged on a side of the driving substrate, each of the plurality of stacked light-emitting unit modules including a first light-emitting unit and a second light-emitting unit stacked and correspondingly arranged; where the first light-emitting unit includes a first light-emitting element, a first connection electrode, and a second connection electrode; the first connection electrode and the second connection electrode are arranged at intervals, the first light-emitting element is electrically connected to the first connection electrode and the second connection electrode, respectively; the first connection electrode and the second connection electrode correspond one-to-one with the first voltage line and the second voltage line but are not all electrically connected; the second light-emitting unit is arranged on a side of the first light-emitting unit away from the driving substrate, the second light-emitting unit includes a second light-emitting element, a third connection electrode, and a fourth connection electrode; the third connection electrode and the fourth connection electrode are arranged at intervals, the second light-emitting element is electrically connected to the third connection electrode and the fourth connection electrode, respectively; the third connection electrode and the fourth connection electrode are electrically connected to the first voltage line and the second voltage line in a one-to-one correspondence, and an orthographic projection of the first light-emitting element on the driving substrate at least partially overlaps with an orthographic projection of the second light-emitting element on the driving substrate.

A second technical solution of the present disclosure provides a method for manufacturing a display panel, including: providing a driving substrate, the driving substrate including a first voltage line and a second voltage line; wherein one of the first voltage line and the second voltage line is a positive power voltage line, and the other is a ground voltage line; manufacturing a first light-emitting layer on a side of the driving substrate, the first light-emitting layer including a plurality of first light-emitting units, each of the plurality of first light-emitting units including a first light-emitting element, a first connection electrode, and a second connection electrode; the first connection electrode and the second connection electrode being arranged at intervals, the first light-emitting element being electrically connected to the first connection electrode and the second connection electrode, respectively; wherein the first connection electrode and the second connection electrode correspond one-to-one with the first voltage line and the second voltage line but are not all electrically connected; manufacturing a second light-emitting layer on a side of the first light-emitting layer away from the driving substrate, the second light-emitting layer including a plurality of second light-emitting units, the plurality of second light-emitting units corresponding one-to-one with the plurality of first light-emitting units, each of the plurality of second light-emitting unit including a second light-emitting element, a third connection electrode, and a fourth connection electrode; the third connection electrode and the fourth connection electrode being arranged at intervals, the second light-emitting element being electrically connected to the third connection electrode and the fourth connection electrode, respectively; wherein the third connection electrode and the fourth connection electrode are electrically connected to the first voltage line and the second voltage line in a one-to-one correspondence; and detecting whether there is an abnormal light-emitting unit among the plurality of second light-emitting units; in a case where the abnormal light-emitting unit exists, removing the light-emitting element of the abnormal light-emitting unit and electrically connecting the first light-emitting unit corresponding to the abnormal light-emitting unit to the first voltage line and the second voltage line, such that the first connection electrode and the second connection electrode of the first light-emitting unit corresponding to the abnormal light-emitting unit are electrically connected to the first voltage line and the second voltage line in a one-to-one correspondence.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a schematic structural view of a first embodiment of a display panel provided in the present disclosure.

FIG. 2 is a schematic structural view of a second embodiment of a display panel provided in the present disclosure.

FIG. 3 is a schematic view of an electrical connection manner of a stacked light-emitting unit module of the display panel shown in FIG. 1.

FIG. 4 is a schematic view of an electrical connection manner of an independent light-emitting unit module of the display panel shown in FIG. 2.

FIG. 5 is a schematic flowchart of a method for manufacturing the display panel provided in some embodiments of the present disclosure.

FIG. 6 is a schematic flowchart of operation S2 in FIG. 5 according to some embodiments.

FIG. 7 is a schematic flowchart of operation S3 in FIG. 5 according to some embodiments.

FIG. 8 is a schematic flowchart of operation S4 in FIG. 5 according to some embodiments.

### DETAILED DESCRIPTION

The technical solutions in the embodiments of the present disclosure will be described clearly and completely in the following in conjunction with the accompanying drawings in the embodiments of the present disclosure. It is evident that the embodiments described below are only some of the embodiments of the present disclosure and not all of them. All other embodiments obtained by those skilled in the art without creative effort shall fall within the scope of protection of the present disclosure.

The terms “first”, “second”, and “third” in the present disclosure are merely used for descriptive purposes and should not be construed as indicating or implying relative importance or implicitly indicating the number of the technical features indicated. Thus, features defined with “first”, “second,” and “third” may explicitly or implicitly include at least one such feature. In the description of the present disclosure, the term “multiple” means at least two, for example, two or three, unless specifically defined otherwise. All directional indications (such as up, down, left, right, front, back, etc.) in the embodiments of the present disclosure are only used to describe the relative positional relationship and movement status of components under a specific posture (as shown in the drawings). If the specific posture changes, the directional indications should also be adjusted accordingly. Furthermore, the terms “include,” “have,” and any variations thereof are intended to cover non-exclusive inclusion. For example, a process, a method, a system, a product, or an apparatus that includes a series of steps or components is not limited to those explicitly listed steps or components but may optionally include other steps or components not listed, or may optionally include inherent other steps or components.

References to “embodiment” in the present disclosure mean that a particular feature, structure, or characteristic described in connection with the embodiment is included in at least one embodiment of the present disclosure. The phrase appearing in various places throughout the specification does not necessarily refer to the same embodiment, and embodiments are not mutually exclusive or alternative unless otherwise indicated. It is explicitly and implicitly understood by those skilled in the art that the embodiments described herein may be combined with other embodiments.

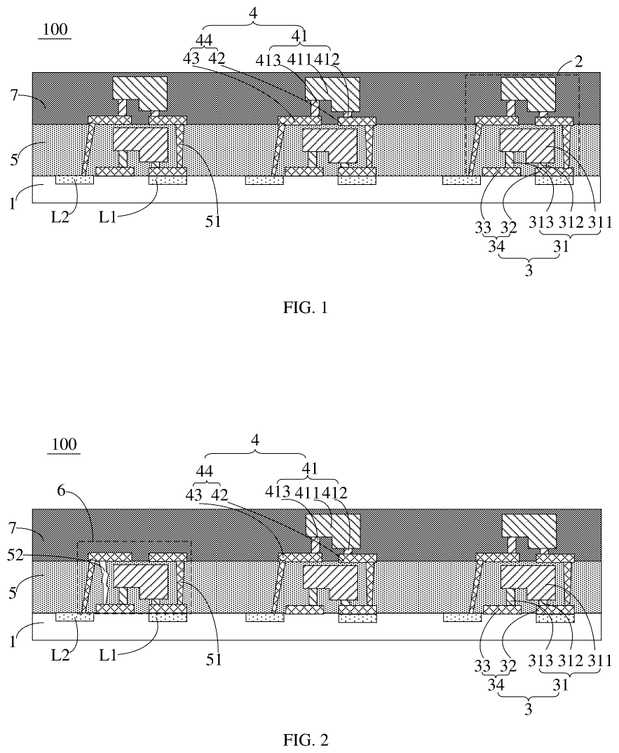

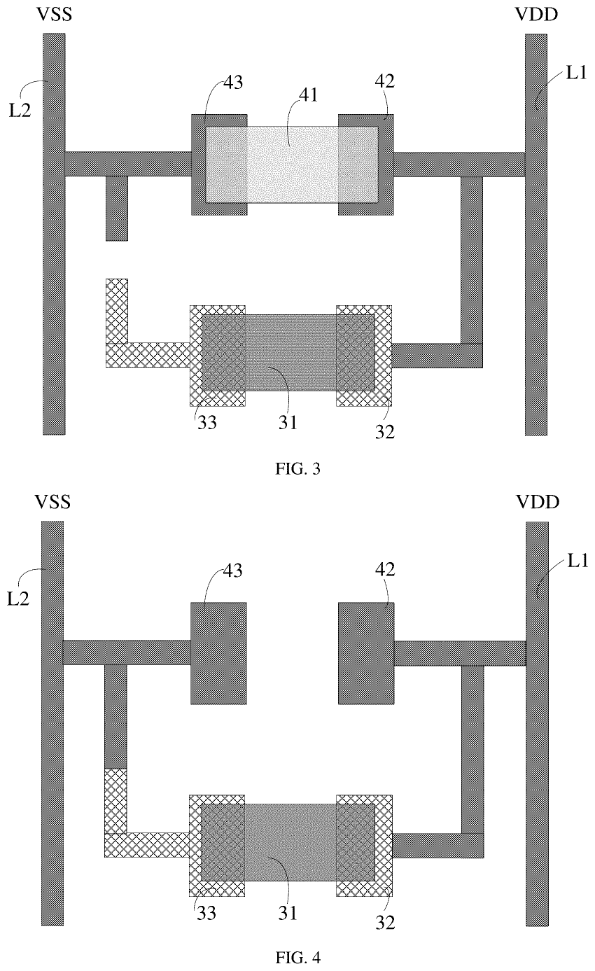

As shown in FIGS. 1 to 4, FIG. 1 is a schematic structural view of a first embodiment of a display panel provided in the present disclosure, FIG. 2 is a schematic structural view of a second embodiment of a display panel provided in the present disclosure, FIG. 3 is a schematic view of an electrical connection manner of a stacked light-emitting unit module of the display panel shown in FIG. 1, and FIG. 4 is a schematic view of an electrical connection manner of an independent light-emitting unit module of the display panel shown in FIG. 2.

As shown in FIGS. 1 and 2, some embodiments of the present disclosure provide a display panel 100. In the embodiments, the display panel 100 includes a driving substrate 1 and a plurality of stacked light-emitting unit modules 2 arranged at intervals.

The driving substrate 1 includes a first voltage line L1 and a second voltage line L2. One of the first voltage line L1 and the second voltage line L2 is a positive power voltage line (VDD), and an other is a ground voltage line (VSS). For example, the first voltage line L1 may be the positive power voltage line and the second voltage line L2 may be the ground voltage line, or the first voltage line L1 may be the ground voltage line and the second voltage line L2 may be the positive power voltage line. In some embodiments, the driving substrate 1 may further include a driving circuit layer (not shown in the drawings) and a thin film transistor layer (not shown in the drawings), etc.

The plurality of stacked light-emitting unit modules 2 arranged at intervals are arranged on a side of the driving substrate 1. Each of the plurality of stacked light-emitting unit modules 2 includes a first light-emitting unit 3 and a second light-emitting unit 4 stacked and correspondingly arranged.

The first light-emitting unit 3 includes a first light-emitting element 31, a first connection electrode 32, and a second connection electrode 33. The first connection electrode 32 and the second connection electrode 33 are arranged at intervals. The first light-emitting element 31 is electrically connected to the first connection electrode 32 and the second connection electrode 33 respectively. In some embodiments, the first connection electrode 32 and the second connection electrode 33 form a first electrode pair 34. A plurality of first light-emitting elements 31 are arranged in one-to-one correspondence with a plurality of first electrode pairs 34. Each of the plurality of first light-emitting elements 31 includes a first epitaxial layer 311, a first contact electrode 312, and a second contact electrode 313. The first contact electrode 312 and the second contact electrode 313 are electrically connected to the first connection electrode 32 and the second connection electrode 33 respectively in a one-to-one correspondence. The first connection electrode 32 and the second connection electrode 33 correspond one-to-one with the first voltage line L1 and the second voltage line L2, but are not all electrically connected.

It should be noted that the “not all electrically connected” herein, in some embodiments, includes: one of the first connection electrode 32 and the second connection electrode 33 is electrically connected to one of the positive power voltage line and the ground voltage line, and the other is not electrically connected to the other of the positive power voltage line and the ground voltage line; or neither the first connection electrode 32 nor the second connection electrode 33 is electrically connected to the positive power voltage line or the ground voltage line. That is, only one of the connection electrodes is electrically connected to the corresponding voltage line, and the other connection electrode is not electrically connected to the corresponding voltage line; or neither of the connection electrodes is electrically connected to the corresponding voltage line. For example, the first connection electrode 32 is electrically connected to the first voltage line L1, while the second connection electrode 33 is not electrically connected to the second voltage line L2; or the first connection electrode 32 is not electrically connected to the first voltage line L1, while the second connection electrode 33 is electrically connected to the second voltage line L2; or neither the first connection electrode 32 is electrically connected to the first voltage line L1, nor the second connection electrode 33 is electrically connected to the second voltage line L2. Since the first connection electrode 32 and the second connection electrode 33 of the first light-emitting unit 3 are not all electrically connected to the first voltage line L1 and the second voltage line L2, the first connection electrode 32 and the second connection electrode 33 of the first light-emitting unit 3 cannot simultaneously receive a VDD signal and a VSS signal, and the first light-emitting element 31 cannot emit a light, and only functions as a backup light-emitting element.

The second light-emitting unit 4 is arranged on a side of the first light-emitting unit 3 away from the driving substrate 1. The second light-emitting unit 4 includes a second light-emitting element 41, a third connection electrode 42, and a fourth connection electrode 43. The third connection electrode 42 and the fourth connection electrode 43 are arranged at intervals. The second light-emitting element 41 is electrically connected to the third connection electrode 42 and the fourth connection electrode 43 respectively. In some embodiments, the third connection electrode 42 and the fourth connection electrode 43 form a second electrode pair 44. A plurality of second light-emitting elements 41 are arranged in one-to-one correspondence with a plurality of second electrode pairs 44. The second light-emitting element 41 includes a second epitaxial layer 411, a third contact electrode 412, and a fourth contact electrode 413. The third contact electrode 412 and the fourth contact electrode 413 are electrically connected to the third connection electrode 42 and the fourth connection electrode 43 respectively in a one-to-one correspondence. The third connection electrode 42 and the fourth connection electrode 43 correspond one-to-one and are electrically connected to the first voltage line L1 and the second voltage line L2, respectively. That is, the second light-emitting element 41 of the second light-emitting unit 4 is electrically connected to both the first voltage line L1 and the second voltage line L2. The third connection electrode 42 and the fourth connection electrode 43 of the second light-emitting unit 4 may receive the VDD signal and the VSS signal, so that the second light-emitting element 41 may realize a light-emitting function. The second light-emitting unit 4 serves as a main light-emitting unit. In some embodiments, an orthographic projection of the first light-emitting element 31 on the driving substrate 1 at least partially overlaps with an orthographic projection of the second light-emitting element 41 on the driving substrate 1.

It can be understood that in some embodiments of the present disclosure, by configuring the display panel 100 to include a plurality of stacked light-emitting unit modules 2 arranged at intervals, and each of the plurality of stacked light-emitting units module 2 including a first light-emitting unit 3 and a second light-emitting unit 4 that are stacked and correspondingly arranged, connecting the first light-emitting element 31 of the first light-emitting unit 3 to the first connection electrode 32 and the second connection electrode 33 respectively, and the first connection electrode 32 and the second connection electrode 33 corresponding one-to-one with the first voltage line L1 and the second voltage line L2 but not all being electrically connected, where the second light-emitting element 41 of the second light-emitting unit 4 is connected to the third connection electrode 42 and the fourth connection electrode 43 respectively, the third connection electrode 42 and the fourth connection electrode 43 correspond one-to-one and are electrically connected to the first voltage line L1 and the second voltage line L2, that is, the second light-emitting element 41 is electrically connected to both the first voltage line L1 and the second voltage line L2, enables the second light-emitting unit 4 to be serve as a main light-emitting unit, and the first light-emitting unit 3 serves as a backup light-emitting unit for the second light-emitting unit 4. In a case where a defective point occurs in the second light-emitting unit 4, that is, in a case where the second light-emitting unit 4 is an abnormal light-emitting unit, the light-emitting element of the abnormal light-emitting unit, that is, the defective second light-emitting element 41, may be removed. The corresponding first light-emitting unit 3 of the abnormal light-emitting unit may be electrically connected to the first voltage line L1 and the second voltage line L2 respectively, so that the first connection electrode 32 and the second connection electrode 33 of the first light-emitting unit 3 corresponding to the abnormal light-emitting unit are electrically connected to the first voltage line L1 and the second voltage line L2 respectively. In this way, the corresponding first light-emitting element 31 of the abnormal light-emitting unit is electrically connected to both the first voltage line L1 and the second voltage line L2, so that the first light-emitting unit 3 may receive the VDD signal and the VSS signal and emit a light. The first light-emitting unit 3 may replace the abnormal light-emitting unit to achieve normal emission, thereby ensuring the display effect of the display panel 100.

With the above configuration, in a case where the second light-emitting element 41 of the stacked light-emitting unit module 2 is abnormal, it is only necessary to change the electrical connection manner between the first light-emitting element 31 and the first voltage line L1 and the second voltage line L2 to enable the first light-emitting element 31 to emit a light, thereby achieving the repair of the abnormal light-emitting unit (defective point). The repair method is simple and efficient. The above configuration not only allows the repair of the abnormal light-emitting unit, but also realizes a simple repair operation. Furthermore, since the first light-emitting unit 3 and the second light-emitting unit 4 are arranged on different layers, and the orthographic projection of the first light-emitting element 31 on the driving substrate 1 at least partially overlaps with the orthographic projection of the second light-emitting element 41 on the driving substrate 1, the arrangement of the first light-emitting unit 3 does not reduce the resolution of the display panel 100, thereby ensuring the distribution density of the second light-emitting elements 41 of the display panel 100, which is beneficial to improving the pixel density and resolution of the display panel 100.

In some embodiments, the orthographic projection of the second light-emitting element 41 of the stacked light-emitting unit module 2 on the driving substrate 1 overlaps with the orthographic projection of the first light-emitting element 31 on the driving substrate 1. That is, the second light-emitting element 41 is located directly above the first light-emitting element 31. It can be understood that by arranging the orthographic projection of the second light-emitting element 41 to overlap with the orthographic projection of the first light-emitting element 31 on the driving substrate 1, it may minimize the impact on the pixel resolution of the display panel 100 caused by misalignment between the second light-emitting element 41 and the first light-emitting element 31. This better ensures that, in case of repairing an abnormal light-emitting unit, the first light-emitting element 31 corresponding to the abnormal light-emitting unit may emit a light normally without being blocked by the remaining second light-emitting units 4, thereby improving the display quality of the display panel 100.

In some embodiments, in each of the plurality of stacked light-emitting unit modules 2, a color of the second light-emitting element 41 of the second light-emitting unit 4 is the same as a color of the first light-emitting element 31 of the first light-emitting unit 3, ensuring that in a case where an abnormality occurs in the second light-emitting element 41 of the stacked light-emitting unit module 2, the second light-emitting element 41 is removed and the first light-emitting element 31 is electrically connected to the first voltage line L1 and the second voltage line L2 respectively through the first connection electrode 32 and the second connection electrode 33. In this case, the first light-emitting element 31 may emit a light of the same color as the second light-emitting element 41, thereby ensuring that the display panel 100 may realize an originally normal image display function. For example, the second light-emitting element 41 of the second light-emitting unit 4 and the first light-emitting element 31 of the first light-emitting unit 3 of the same stacked light-emitting unit module 2 are both red, or both green, or both blue. In some embodiments, the second light-emitting element 41 and the first light-emitting element 31 of the same stacked light-emitting unit module 2 may also be configured with other colors simultaneously.

In some embodiments, as shown in FIGS. 1 to 3, among the first connection electrode 32 and the second connection electrode 33 of the first light-emitting unit 3 of the each of the plurality of stacked light-emitting unit modules 2, only one of the connection electrodes is electrically connected to a corresponding voltage line, and the other connection electrode is not electrically connected to a corresponding voltage line. In some embodiments, the first connection electrode 32 of the first light-emitting unit 3 of the stacked light-emitting unit module 2 is arranged corresponding to and electrically connected to the first voltage line L1, and the second connection electrode 33 is arranged corresponding to but not electrically connected to the second voltage line L2. In some embodiments, a first encapsulation layer 5 is arranged on the side of the first light-emitting unit 3 away from the driving substrate 1. The first encapsulation layer 5 covers the first light-emitting unit 3. The second light-emitting unit 4 is arranged on a side of the first encapsulation layer 5 away from the first light-emitting unit 3. At a position which the first encapsulation layer 5 corresponds to the first connection electrode 32 of the first light-emitting unit 3 and the third connection electrode 42 of the second light-emitting unit 4, a first via hole 51 is defined. The first via hole 51 penetrates the first encapsulation layer 5 and exposes a portion of the first connection electrode 32. The third connection electrode 42 extends into the first via hole 51 and is in contact with and electrically connected to the first connection electrode 32. The third connection electrode 42 is electrically connected to the first voltage line L1 through the first connection electrode 32. The fourth connection electrode 43 penetrates the first encapsulation layer 5 and is directly connected to the second voltage line L2, so that the second light-emitting element 41 may receive VDD and VSS signals to emit a light.

In some embodiments, the first connection electrode 32 of the first light-emitting unit 3 of the stacked light-emitting unit module 2 may be arranged corresponding to but not electrically connected to the first voltage line L1, and the second connection electrode 33 may be arranged corresponding to and electrically connected to the second voltage line L2. The first via hole 51 is defined on the first encapsulation layer 5 at a position corresponding to the second connection electrode 33 of the first light-emitting unit 3 and the fourth connection electrode 43 of the second light-emitting unit 4. The first via hole 51 penetrates the first encapsulation layer 5 and exposes a portion of the second connection electrode 33. The fourth connection electrode 43 extends into the first via hole 51 and is in contact with and electrically connected to the second connection electrode 33. The fourth connection electrode 43 is thereby electrically connected to the second voltage line L2 through the second connection electrode 33. The third connection electrode 42 penetrates the first encapsulation layer 5 and is directly connected to the first voltage line L1, so that the second light-emitting element 41 may receive VDD and VSS signals to emit a light.

As shown in FIG. 2, in some embodiments, the display panel 100 further includes an independent light-emitting unit module 6. The independent light-emitting unit module 6 is arranged on the side of the driving substrate 1. The light-emitting module 6 and the stacked light emitting unit module 2 are arranged at intervals. The independent light-emitting unit module 6 includes the first light-emitting unit 3, but does not include the second light-emitting element 41. The first connection electrode 32 and the second connection electrode 33 of the independent light-emitting unit module 6 are electrically connected to the first voltage line L1 and the second voltage line L2 respectively in a one-to-one correspondence. That is, in some embodiments, the first light-emitting element 31 of the independent light-emitting unit module 6 is electrically connected to both the first voltage line L1 and the second voltage line L2. The first light-emitting unit 3 of the independent light-emitting unit module 6 may receive a signal to emit a light. In some embodiments, the structure and electrical connection manner of the stacked light-emitting unit module 2 are the same as those of the stacked light-emitting unit module 2 in the first embodiment.

In some embodiments, as shown in FIG. 2, the independent light-emitting unit module 6 further includes a first encapsulation layer 5, a third connection electrode 42, and a fourth connection electrode 43. The first encapsulation layer 5 covers the first light-emitting unit 3. The third connection electrode 42 and the fourth connection electrode 43 are arranged on the side of the first encapsulation layer 5 away from the driving substrate 1. As shown in FIG. 4, the third connection electrode 42 and the fourth connection electrode 43 of the independent light-emitting unit module 6 are electrically connected to the first connection electrode 32 and the second connection electrode 33 respectively in a one-to-one correspondence. The first connection electrode 32 of the independent light-emitting unit module 6 is directly arranged corresponding to and electrically connected to the first voltage line L1. The second connection electrode 33 of the independent light-emitting unit module 6 is electrically connected to the second voltage line L2 through the fourth connection electrode 43. That is, the fourth connection electrode 43 of the independent light-emitting unit module 6 is originally directly connected to the second voltage line L2, and the second connection electrode 33 of the first light-emitting unit 3 of the independent light-emitting unit module 6 is electrically connected to the fourth connection electrode 43, thereby realizing electrical connection to the second voltage line L2. This allows the first light-emitting unit 3 of the independent light-emitting unit module 6 to be electrically connected to both the first voltage line L1 and the second voltage line L2, so as to receive VDD and VSS signals for light emission.

In some embodiments, as shown in FIG. 2, a second via hole 52 is defined on the first encapsulation layer 5 at the position corresponding to the fourth connection electrode 43 and the second connection electrode 33 of the independent light-emitting unit module 6. The second via hole 52 penetrates the first encapsulation layer 5 and exposes the portion of the second connection electrode 33 of the independent light-emitting unit module 6. The fourth connection electrode 43 extends into the second via hole 52 and is in contact with and electrically connected to the second connection electrode 33. Alternatively, an electrical connection between the fourth connection electrode 43 and the second connection electrode 33 of the independent light-emitting unit module 6 may be realized by filling conductive paste into the second via hole 52. Alternatively, solder may be filled into the second via hole 52, and the fourth connection electrode 43 of the independent light-emitting unit module 6 and the second connection electrode 33 may be soldered together using a soldering method to realize an electrical connection between the two.

In some embodiments, the display panel 100 of the second embodiment may actually be a new structure formed by repairing an abnormal second light-emitting unit 4 in the plurality of stacked light-emitting unit modules 2 of the display panel 100 of the first embodiment. This involves removing the light-emitting element of the abnormal light-emitting unit, and then electrically connecting the first connection electrode 32 and the second connection electrode 33 of the corresponding first light-emitting unit 3 to the first voltage line L1 and the second voltage line L2 in a one-to-one correspondence. That is, the display panel 100 of the first embodiment is a structure before the repair of the abnormal light-emitting unit, and the display panel 100 of the second embodiment is a structure after the repair of the abnormal light-emitting unit.

As shown in FIGS. 1 and 2, in some embodiments, a second encapsulation layer 7 is further arranged on a side of the second light-emitting unit 4 away from the first light-emitting unit 3. The second encapsulation layer 7 covers the second light-emitting unit 4. Taking the display panel 100 of the first embodiment as an example, in a case where there are abnormal light-emitting units among the second light-emitting units 4 in the plurality of stacked light-emitting unit modules 2, when performing repair on the abnormal light-emitting units, it is necessary to first remove a portion of the second encapsulation layer 7 corresponding to a position of the abnormal light-emitting unit to expose the light-emitting element of the abnormal light-emitting unit. The light-emitting element of the abnormal light-emitting unit is removed. The first connection electrode 32 and the second connection electrode 33 of the first light-emitting unit 3 corresponding to the abnormal light-emitting unit are electrically connected to the first voltage line L1 and the second voltage line L2 respectively. In some embodiments, for example, the first connection electrode 32 of the first light-emitting unit 3 corresponding to the abnormal light-emitting unit is directly electrically connected to the first voltage line L1. By defining the second via hole 52 on the first encapsulation layer 5, the second connection electrode 33 of the first light-emitting unit 3 corresponding to the abnormal light-emitting unit is electrically connected to the fourth connection electrode 43 of the abnormal light-emitting unit through the second via hole 52. A position of a removed light-emitting element of the abnormal light-emitting unit and the portion of the second encapsulation layer 7 that is removed may be filled with encapsulant, thereby forming the structure of the display panel 100 as shown in FIG. 2

In some embodiments, the side of the second light-emitting unit 4 of the display panel 100 away from the second light-emitting unit 4 may originally be arranged without the second encapsulation layer 7. The second light-emitting unit 4 may be encapsulated after the repair of the abnormal second light-emitting unit 4 in the stacked light-emitting unit module 2, that is, after the light-emitting element of the abnormal light-emitting unit is removed and the corresponding first light-emitting unit 3 is electrically connected to both the first voltage line L1 and the second voltage line L2. The second encapsulation layer 7 is then formed on the side of the second light-emitting unit 4 away from the first light-emitting unit 3.

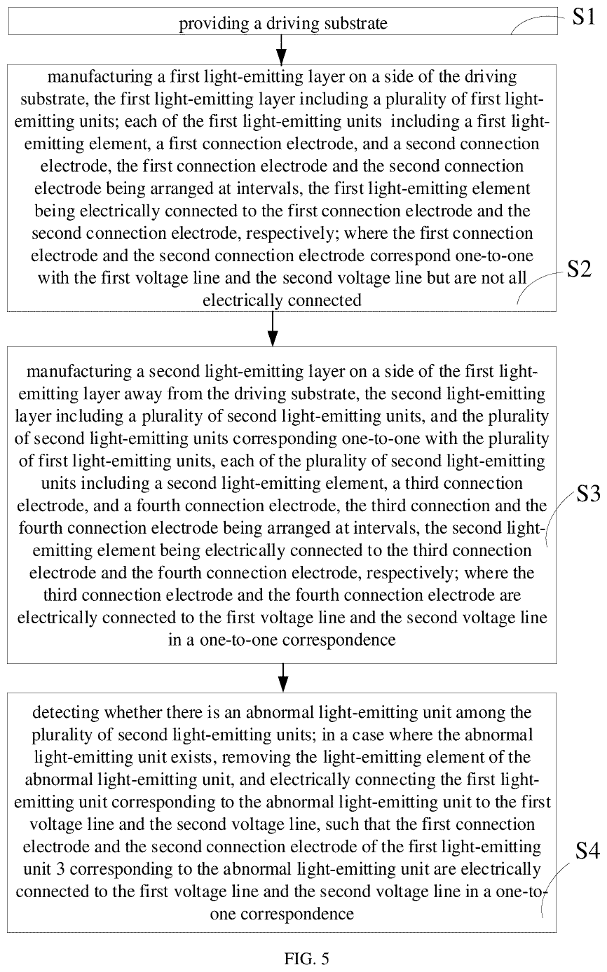

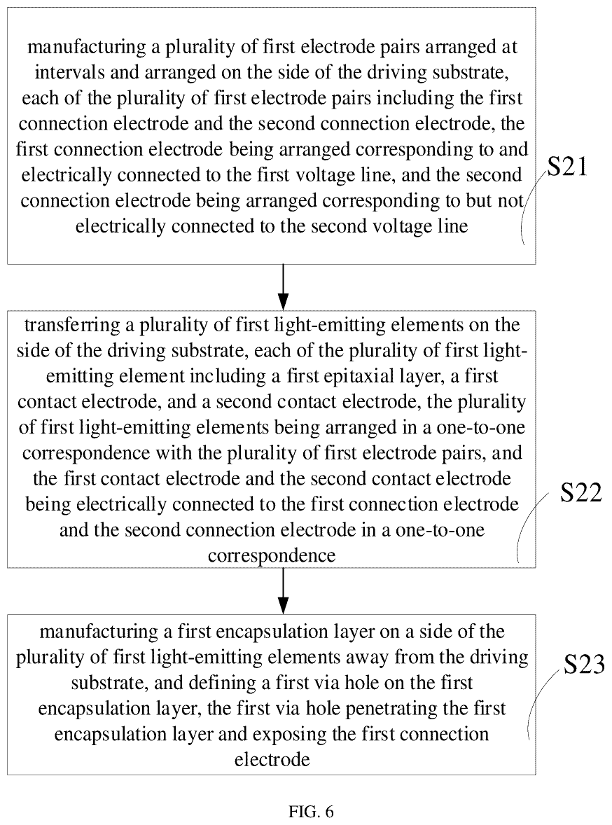

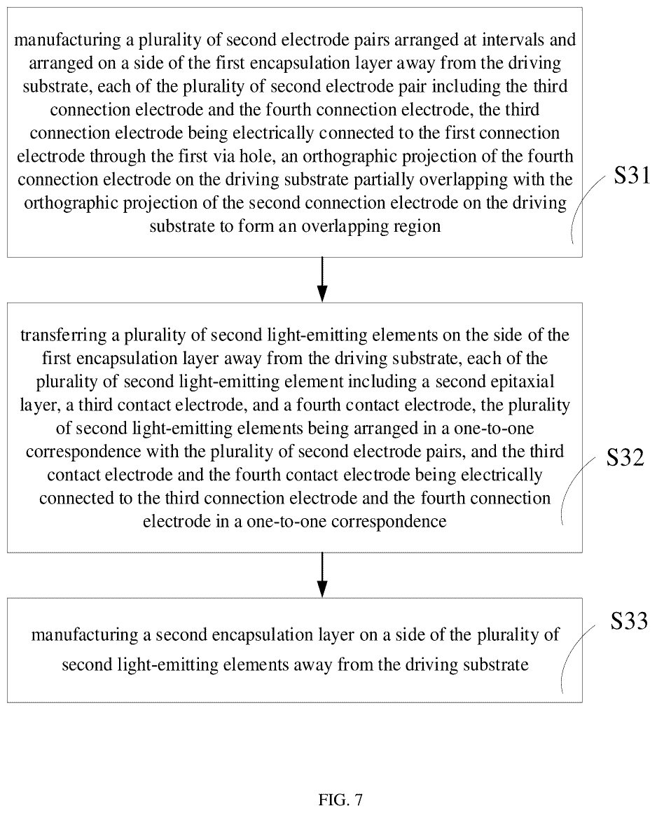

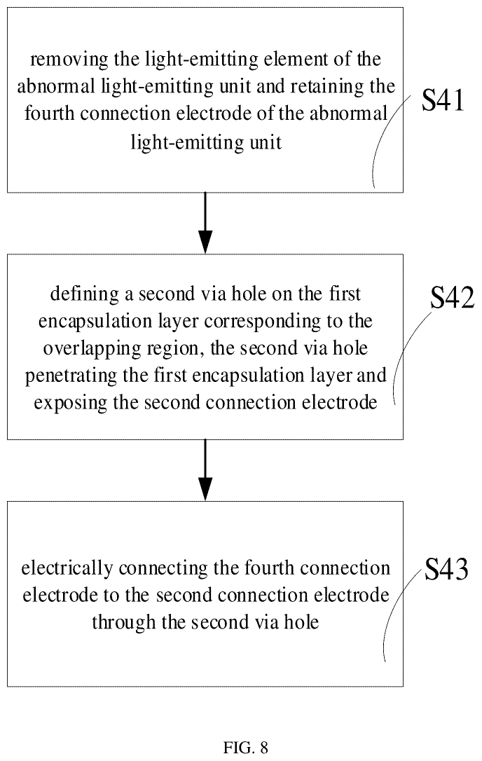

As shown in FIGS. 5 to 8, FIG. 5 is a schematic flowchart of a method for manufacturing the display panel provided in some embodiments of the present disclosure, FIG. 6 is a schematic flowchart of operation S2 in FIG. 5 according to some embodiments, FIG. 7 is a schematic flowchart of operation S3 in FIG. 5 according to some embodiments, and FIG. 8 is a schematic flowchart of operation S4 in FIG. 5 according to some embodiments.

As shown in FIG. 5, some embodiments of the present disclosure provide a method for manufacturing a display panel 100, which is configured for manufacturing the display panel 100 as shown in FIG. 1 or FIG. 2.

In some embodiments, the method for manufacturing the display panel 100 may include a manufacturing process of the display panel 100 and a repair method for the display panel 100 formed through the manufacturing process.

In some embodiments, the method for manufacturing the display panel 100 includes the following operations.

Operation S1: providing a driving substrate 1.

In some embodiments, the driving substrate 1 is first provided. The driving substrate 1 includes a first voltage line L1 and a second voltage line L2. One of the first voltage line L1 and the second voltage line L2 is a positive power voltage line, and the other is a ground voltage line. In some embodiments, the driving substrate 1 may further include a driving circuit layer and a thin film transistor layer, etc.

Operation S2: manufacturing a first light-emitting layer on a side of the driving substrate 1, the first light-emitting layer including a plurality of first light-emitting units 3; each of the first light-emitting units 3 including a first light-emitting element 31, a first connection electrode 32, and a second connection electrode 33, the first connection electrode 32 and the second connection electrode 33 being arranged at intervals, the first light-emitting element 31 being electrically connected to the first connection electrode 32 and the second connection electrode 33, respectively; where the first connection electrode 32 and the second connection electrode 33 correspond one-to-one with the first voltage line L1 and the second voltage line L2 but are not all electrically connected.

In some embodiments, the first light-emitting layer is manufactured on the side of the driving substrate 1. The first light-emitting layer includes the plurality of first light-emitting units 3. Each of the plurality of first light-emitting units 3 includes the first light-emitting element 31, the first connection electrode 32, and the second connection electrode 33. The first connection electrode 32 and the second connection electrode 33 are arranged at intervals. The first light-emitting element 31 is electrically connected to the first connection electrode 32 and the second connection electrode 33, respectively. The first connection electrode 32 and the second connection electrode 33 correspond one-to-one with the first voltage line L1 and the second voltage line L2 but are not all electrically connected.

It should be noted that the “not all electrically connected” herein, in some embodiments, includes: one of the first connection electrode 32 and the second connection electrode 33 is electrically connected to one of the positive power voltage line and the ground voltage line, and the other is not electrically connected to the other of the positive power voltage line and the ground voltage line; or neither the first connection electrode 32 nor the second connection electrode 33 is electrically connected to the positive power voltage line or the ground voltage line. That is, only one of the connection electrodes is electrically connected to the corresponding voltage line, and the other connection electrode is not electrically connected to the corresponding voltage line; or neither of the connection electrodes is electrically connected to the corresponding voltage line. For example, the first connection electrode 32 is electrically connected to the first voltage line L1, while the second connection electrode 33 is not electrically connected to the second voltage line L2; or the first connection electrode 32 is not electrically connected to the first voltage line L1, while the second connection electrode 33 is electrically connected to the second voltage line L2; or neither the first connection electrode 32 is electrically connected to the first voltage line L1, nor the second connection electrode 33 is electrically connected to the second voltage line L2. Since the first connection electrode 32 and the second connection electrode 33 of the first light-emitting unit 3 are not all electrically connected to the first voltage line L1 and the second voltage line L2, the first connection electrode 32 and the second connection electrode 33 of the first light-emitting unit 3 cannot receive signals, and the first light-emitting element 31 cannot emit a light and only functions as a backup light-emitting element.

In some embodiments, as shown in FIG. 6, the operation S2 of the manufacturing the first light-emitting layer on the side of the driving substrate 1 includes the following operations.

Operation S21: manufacturing a plurality of first electrode pairs 34 arranged at intervals and arranged on the side of the driving substrate 1, each of the plurality of first electrode pairs 34 including the first connection electrode 32 and the second connection electrode 33, the first connection electrode 32 being arranged corresponding to and electrically connected to the first voltage line L1, and the second connection electrode 33 being arranged corresponding to but not electrically connected to the second voltage line L2.

In some embodiments, the plurality of first electrode pairs 34 are arranged on the side of the driving substrate 1 and are arranged at intervals. Each of the plurality of first electrode pair 34 includes the first connection electrode 32 and the second connection electrode 33. The first connection electrode 32 and the second connection electrode 33 are arranged at intervals.

The first connection electrode 32 and the second connection electrode 33 correspond one-to-one with the first voltage line L1 and the second voltage line L2 but are not all electrically connected. In some embodiments, the first connection electrode 32 is arranged corresponding to and electrically connected to the first voltage line L1, and the second connection electrode 33 is arranged corresponding to but not electrically connected to the second voltage line L2.

Operation S22: transferring a plurality of first light-emitting elements 31 on the side of the driving substrate 1, each of the plurality of first light-emitting element 31 including a first epitaxial layer 311, a first contact electrode 312, and a second contact electrode 313, the plurality of first light-emitting elements 31 being arranged in a one-to-one correspondence with the plurality of first electrode pairs 34, and the first contact electrode 312 and the second contact electrode 313 being electrically connected to the first connection electrode 32 and the second connection electrode 33 in a one-to-one correspondence.

In some embodiments, the plurality of first light-emitting elements 31 are transferred on the side of the driving substrate 1, and the plurality of first light-emitting elements 31 are arranged in a one-to-one correspondence with the plurality of first electrode pairs 34. Each of the plurality of first light-emitting element 31 includes the first epitaxial layer 311, the first contact electrode 312 and the second contact electrode 313. The first contact electrode 312 and the second contact electrode 313 of the plurality of first light-emitting elements 31 are electrically connected to the first connection electrode 32 and the second connection electrode 33 on the side of the driving substrate 1 in a one-to-one correspondence.

Since the first connection electrode 32 is arranged corresponding to and electrically connected to the first voltage line L1, the second connection electrode 33 is arranged corresponding to but not electrically connected to the second voltage line L2, and the first contact electrode 312 and the second contact electrode 313 of the first light-emitting element 31 are electrically connected to the first connection electrode 32 and the second connection electrode 33 on the side of the driving substrate 1 in a one-to-one correspondence, the first light-emitting element 31 is electrically connected to the first voltage line L1 but not electrically connected to the second voltage line L2. In this operation, the first light-emitting element 31 cannot receive VDD and VSS signals or emit a light, and only functions as a backup light-emitting element.

Operation S23: manufacturing a first encapsulation layer 5 on a side of the plurality of first light-emitting elements 31 away from the driving substrate 1, and defining a first via hole 51 on the first encapsulation layer 5, the first via hole 51 penetrating the first encapsulation layer 5 and exposing the first connection electrode 32.

In some embodiments, the first encapsulation layer 5 is manufactured on the side of the plurality of first light-emitting elements 31 away from the driving substrate 1 to encapsulate and protect the plurality of first light-emitting elements 31. Then, the first via hole 51 is defined on the first encapsulation layer 5. The first via hole 51 penetrates the first encapsulation layer 5 and exposes the first connection electrode 32. In some embodiments, the first via hole 51 is defined at a position corresponding to the first connection electrode 32, such that a portion of the first connection electrode 32 is exposed through the first via hole 51.

Operation S3: manufacturing a second light-emitting layer on a side of the first light-emitting layer away from the driving substrate 1, the second light-emitting layer including a plurality of second light-emitting units 4, and the plurality of second light-emitting units 4 corresponding one-to-one with the plurality of first light-emitting units 3, each of the plurality of second light-emitting units 4 including a second light-emitting element 41, a third connection electrode 42, and a fourth connection electrode 43, the third connection 42 and the fourth connection electrode 43 being arranged at intervals, the second light-emitting element 41 being electrically connected to the third connection electrode 42 and the fourth connection electrode 43, respectively; where the third connection electrode 42 and the fourth connection electrode 43 are electrically connected to the first voltage line L1 and the second voltage line L2 in a one-to-one correspondence.

In some embodiments, the second light-emitting layer is manufactured on the side of the first light-emitting layer away from the driving substrate 1. The second light-emitting layer includes the plurality of second light-emitting units 4. The plurality of the second light-emitting units 5 are arranged in a one-to-one correspondence with the plurality of first light-emitting units 3 in the first light-emitting layer. In some embodiments, the second light-emitting unit 4 at least partially overlaps with a projection of a corresponding first light-emitting unit 3. It can be understood that by arranging the second light-emitting unit 4 to at least partially overlap with the projection of the corresponding first light-emitting unit 3, the arrangement of the first light-emitting unit 3 does not reduce the resolution of the formed display panel 100, ensures the distribution density of the second light-emitting elements 41 of the formed display panel 100, and is beneficial to improving the pixel density and resolution of the formed display panel 100.

In some embodiments, the second light-emitting unit 4 includes the second light-emitting element 41, the third connection electrode 42, and the fourth connection electrode 43. The third connection electrode 42 and the fourth connection electrode 43 are arranged at intervals. The second light-emitting element 41 is electrically connected to the third connection electrode 42 and the fourth connection electrode 43, respectively. The third connection electrode 42 and the fourth connection electrode 43 are electrically connected to the first voltage line L1 and the second voltage line L2 in a one-to-one correspondence.

Since the third connection electrode 42 and the fourth connection electrode 43 are electrically connected to the first voltage line L1 and the second voltage line L2 in a one-to-one correspondence, and the second light-emitting element 41 is electrically connected to the third connection electrode 42 and the fourth connection electrode 43 respectively, the second light-emitting element 41 is electrically connected to both the first voltage line L1 and the second voltage line L2, and may simultaneously receive the VDD signal and the VSS signal. The second light-emitting element 41 may emit a light and function as the main light-emitting element.

In some embodiments, as shown in FIG. 7, the operation S3 of the manufacturing the second light-emitting layer on the side of the first light-emitting layer away from the driving substrate 1 includes the following operations.

S31: manufacturing a plurality of second electrode pairs 44 arranged at intervals and arranged on a side of the first encapsulation layer 5 away from the driving substrate 1, each of the plurality of second electrode pair 44 including the third connection electrode 42 and the fourth connection electrode 43, the third connection electrode 42 being electrically connected to the first connection electrode 32 through the first via hole 51, an orthographic projection of the fourth connection electrode 43 on the driving substrate 1 partially overlapping with the orthographic projection of the second connection electrode 33 on the driving substrate 1 to form an overlapping region.

In some embodiments, the plurality of second electrode pairs 44 are manufactured on the side of the first encapsulation layer 5 away from the driving substrate 1 and are arranged at intervals from each other. Each of the plurality of second electrode pair 44 includes the third connection electrode 42 and the fourth connection electrode 43 arranged at intervals. The third connection electrode 42 and the fourth connection electrode 43 are electrically connected to the first voltage line L1 and the second voltage line L2 in a one-to-one correspondence.

In some embodiments, the third connection electrode 42 is electrically connected to the first connection electrode 32 through the first via hole 51 in the first encapsulation layer 5. In some embodiments, an end of the third connection electrode 42 extends into the first via hole 51 and is in contact with and electrically connected to the first connection electrode 32. That is, the first connection electrode 32 is electrically connected to the first voltage line L1, and the third connection electrode 42 is electrically connected to the first voltage line L1 through a via hole connection with the first connection electrode 32. In some embodiments, the fourth connection electrode 43 is directly electrically connected to the second voltage line L2, and in this operation, the second connection electrode 33 is not electrically connected to the fourth connection electrode 43.

In some embodiments, the orthographic projection of the fourth connection electrode 43 on the driving substrate 1 partially overlaps with the orthographic projection of the second connection electrode 33 on the driving substrate 1 to form the overlapping region. In some embodiments, the plurality of second electrode pairs 44 are arranged in a one-to-one correspondence with the plurality of first electrode pairs 34, the third connection electrode 42 corresponds to the first connection electrode 32, and the fourth connection electrode 43 corresponds to the second connection electrode 33. It can be understood that by arranging the orthographic projection of the fourth connection electrode 43 to partially overlap with the orthographic projection of the second connection electrode 33 on the driving substrate 1 to form the overlapping region, in a case where the second light-emitting element 41 of the abnormal light-emitting unit needs to be repaired in a subsequent operation, the electrical connection between the fourth connection electrode 43 and the second connection electrode 33 may be conveniently realized, thereby facilitating the electrical connection between the second connection electrode 33 and the second voltage line L2, so as to realize a light emission using the first light-emitting unit 3 as a substitute for the abnormal light-emitting unit, thereby completing the repair of the abnormal light-emitting unit.

Operation S32: transferring a plurality of second light-emitting elements 41 on the side of the first encapsulation layer 5 away from the driving substrate 1, each of the plurality of second light-emitting element 41 including a second epitaxial layer 411, a third contact electrode 412, and a fourth contact electrode 413, the plurality of second light-emitting elements 41 being arranged in a one-to-one correspondence with the plurality of second electrode pairs 44, and the third contact electrode 412 and the fourth contact electrode 413 being electrically connected to the third connection electrode 42 and the fourth connection electrode 43 in a one-to-one correspondence.

In some embodiments, after manufacturing the plurality of second electrode pairs 44, the plurality of second light-emitting elements 41 are transferred on the side of the first encapsulation layer 5 away from the driving substrate 1, and the plurality of second light-emitting elements 41 are arranged in a one-to-one correspondence with the plurality of second electrode pairs 44. In some embodiments, each of the plurality of second light-emitting elements 41 includes a second epitaxial layer 411, a third contact electrode 412, and a fourth contact electrode 413. The third contact electrode 412 and the fourth contact electrode 413 are arranged at intervals and are electrically connected to the third connection electrode 42 and the fourth connection electrode 43 in a one-to-one correspondence. In some embodiments, the third contact electrode 412 is electrically connected to the third connection electrode 42, and the fourth contact electrode 413 is electrically connected to the fourth connection electrode 43, so that the second light-emitting element 41 is electrically connected to both the third connection electrode 42 and the fourth connection electrode 43, thereby realizing the electrical connection of the second light-emitting element 41 to the first voltage line L1 and the second voltage line L2, so that the second light-emitting element 41 may emit a light.

In some embodiments, the plurality of second light-emitting units 4 in the second light-emitting layer are arranged in a one-to-one correspondence with the plurality of first light-emitting units 3, and a color of the second light-emitting element 41 is the same as a color of a corresponding first light-emitting element 31. This ensures that, in a case where an abnormality occurs in the second light-emitting element 41 and the abnormal light-emitting unit is repaired, the first light-emitting element 31 of the corresponding first light-emitting unit 3 may emit a light of the same color as the abnormal light-emitting unit, thereby ensuring the repair effect of the abnormal light-emitting unit and maintaining the display effect of the display panel 100.

In some embodiments, the orthographic projection of the plurality of second light-emitting elements 41 on the driving substrate 1 overlaps with the orthographic projection of the plurality of first light-emitting elements 31 on the driving substrate 1. That is, the second light-emitting element 41 is located directly above the first light-emitting element 31. It can be understood that by arranging the orthographic projection of the second light-emitting element 41 to overlap with the orthographic projection of the first light-emitting element 31 on the driving substrate 1, the impact on the pixel resolution of the display panel 100 caused by misalignment between the second light-emitting element 41 and the first light-emitting element 31 may be minimized, and it may be better ensured that, during the repair of an abnormal light-emitting unit, the corresponding first light-emitting element 31 may emit a light normally without being blocked by remaining second light-emitting units 4, thereby improving the display quality of the display panel 100.

Operation S33: manufacturing a second encapsulation layer 7 on a side of the plurality of second light-emitting elements 41 away from the driving substrate 1.

In some embodiments, after the second light-emitting layer is manufactured, a second encapsulation layer 7 is manufactured on the side of the plurality of second light-emitting elements 41 away from the driving substrate 1. The second encapsulation layer 7 covers the plurality of second light-emitting units 4 to provide encapsulation protection for the second light-emitting units 4.

In some embodiments, the manufacturing process of the display panel 100 includes operations S1 to S3 in the method for manufacturing the display panel 100.

In some embodiments, after operation S33 is completed, the structure of the display panel 100 as shown in FIG. 1 may be obtained.

Furthermore, the method for manufacturing the display panel 100 further includes a repair method for the display panel 100 formed by the manufacturing process including operations S1 to S3. In some embodiments, the method for manufacturing the display panel 100 further includes the following operations.

Operation S4: detecting whether there is an abnormal light-emitting unit among the plurality of second light-emitting units 4; in a case where the abnormal light-emitting unit exists, removing the light-emitting element of the abnormal light-emitting unit, and electrically connecting the first light-emitting unit 3 corresponding to the abnormal light-emitting unit to the first voltage line L1 and the second voltage line L2, such that the first connection electrode 32 and the second connection electrode 33 of the first light-emitting unit 3 corresponding to the abnormal light-emitting unit are electrically connected to the first voltage line L1 and the second voltage line L2 in a one-to-one correspondence.

In some embodiments, whether there is an abnormal light-emitting unit among the plurality of second light-emitting units 4 is detected. In a case where an abnormal light-emitting unit is detected, the light-emitting element of the abnormal light-emitting unit is removed, i.e., the abnormal second light-emitting element 41 is removed, and the first light-emitting unit 3 corresponding to the abnormal light-emitting unit is electrically connected to the first voltage line L1 and the second voltage line L2, so that the first light-emitting unit 3 corresponding to the abnormal light-emitting unit may receive the VDD signal and the VSS signal to emit a light normally. The first light-emitting unit 3 corresponding to the abnormal light-emitting unit is configured to replace the abnormal light-emitting unit to emit the light, thereby repairing the abnormal light-emitting unit (defective point).

In some embodiments, as shown in FIG. 8, the operation S4 of the removing the light-emitting element of the abnormal light-emitting unit and electrically connecting the first light-emitting unit 3 corresponding to the abnormal light-emitting unit to the first voltage line L1 and the second voltage line L2 includes the following operations.

Operation S41: removing the light-emitting element of the abnormal light-emitting unit and retaining the fourth connection electrode 43 of the abnormal light-emitting unit.

In some embodiments, after detecting that there is an abnormal light-emitting unit among the plurality of second light-emitting units 4, the light-emitting element of the abnormal light-emitting unit is removed, i.e., the second light-emitting element 41 of the abnormal second light-emitting unit 4 is removed, while the fourth connection electrode 43 of the abnormal second light-emitting unit 4 is retained. The fourth connection electrode 43 is electrically connected to the second voltage line L2.

In some embodiments, the third connection electrode 42 is electrically connected to the first connection electrode 32 through the first via hole 51, and the third connection electrode 42 is electrically connected to the first voltage line L1. The fourth connection electrode 43 and the third connection electrode 42 of the abnormal light-emitting unit may both be retained simultaneously.

In some embodiments, when removing the light-emitting element of the abnormal light-emitting unit, it is necessary to first remove a portion of the second encapsulation layer 7 corresponding to the abnormal light-emitting unit, so that the light-emitting element of the abnormal light-emitting unit is exposed.

Operation S42: defining a second via hole 52 on the first encapsulation layer 5 corresponding to the overlapping region, the second via hole 52 penetrating the first encapsulation layer 5 and exposing the second connection electrode 33.

In some embodiments, the second via hole 52 is defined on the first encapsulation layer 5, and the second via hole 52 penetrates the first encapsulation layer 5 and exposes the second connection electrode 33. In some embodiments, the orthographic projection of the fourth connection electrode 43 on the driving substrate 1 partially overlaps with the orthographic projection of the second connection electrode 33 on the driving substrate 1, forming the overlapping region. The second via hole 52 is defined at the overlapping region to facilitate the subsequent electrical connection between the second connection electrode 33 and the fourth connection electrode 43.

Operation S43: electrically connecting the fourth connection electrode 43 to the second connection electrode 33 through the second via hole 52.

In some embodiments, the fourth connection electrode 43 is electrically connected to the second connection electrode 33 through the second via hole 52. This may be achieved by filling conductive paste into the second via hole 52 to realize electrical connection between the fourth connection electrode 43 and the second connection electrode 33, or by filling solder into the second via hole 52 and using a soldering method to solder the fourth connection electrode 43 to the second connection electrode 33 to realize electrical connection between them.

Since the fourth connection electrode 43 is electrically connected to the second voltage line L2, and the second connection electrode 33 is not originally electrically connected to the second voltage line L2, by electrically connecting the fourth connection electrode 43 to the second connection electrode 33 through the second via hole 52, electrical connection between the second connection electrode 33 and the second voltage line L2 may be realized. As a result, the first light-emitting unit 3 corresponding to the abnormal light-emitting unit may be electrically connected to both the second voltage line L2 and the first voltage line L1, so that the first light-emitting unit 3 may receive both the VDD signal and the VSS signal and thus emit a light, thereby enabling the first light-emitting unit 3 to replace the abnormal light-emitting unit for light emission. This achieves the repair of the abnormal light-emitting unit without affecting the display effect of the display panel 100, and without affecting the resolution and display quality of the display panel 100.

In some embodiments, after the fourth connection electrode 43 is electrically connected to the second connection electrode 33 in operation S43, the portion of the second encapsulation layer 7 at the position of the removed light-emitting element of the abnormal light-emitting unit is further filled with encapsulant to level, such that the second encapsulation layer 7 may protect the second light-emitting unit 4.

In some embodiments, the detecting whether there is an abnormal light-emitting unit among the plurality of second light-emitting units 4 in operation S4 occurs after the manufacturing the second encapsulation layer 7 in operation S33, so as to repair abnormalities (defective points) that occur during subsequent use of the manufactured display panel 100. Operation S4 serves as a repair method for the display panel 100 after formation, that is, a method for repairing the abnormalities in the display panel 100 that occur during the user's use of the panel. The repair method of operation S4 has significant advantages for repairing abnormalities in the display panel 100 during use: it only requires removal of the abnormal light-emitting unit and electrical connection of the corresponding first light-emitting unit 3 to the first voltage line L1 and the second voltage line L2, which allows for simple and efficient repair of the abnormal light-emitting unit.

In some embodiments, after operation S43 is completed, the structure of the display panel 100 as shown in FIG. 2 may be obtained. That is, after repairing the display panel 100 manufactured as shown in FIG. 1, the structure of the display panel 100 as shown in FIG. 2 may be obtained.

In some embodiments, operation S3 may not include the manufacturing the second encapsulation layer 7 on the side of the plurality of second light-emitting elements 41 away from the driving substrate 1 as described in operation S33. In operation S4, detecting whether there is an abnormal light-emitting unit among the plurality of second light-emitting units 4, in a case where the abnormal light-emitting unit exists, the light-emitting element of the abnormal light-emitting unit may be removed, and a new second light-emitting element 41 may be directly re-transferred to the position of the removed light-emitting element of the abnormal light-emitting unit, so that a re-transferred new second light-emitting element 41 is electrically connected to both the first voltage line L1 and the second voltage line L2 to emit a light, thereby directly using the re-transferred new second light-emitting element 41 to replace the light-emitting element of the abnormal light-emitting unit. In operation S4, the electrical connection manner of the first light-emitting unit 3 corresponding to the abnormal light-emitting unit with respect to the first voltage line L1 and the second voltage line L2 remains unchanged, that is, the first light-emitting unit 3 corresponding to the abnormal light-emitting unit is still not electrically connected to both the first voltage line L1 and the second voltage line L2. In this operation, the first light-emitting element 31 still serves as a backup light-emitting element and does not emit light. That is, operation S4 may also serve as a repair method for the abnormal second light-emitting unit 4 during the manufacturing process of the display panel 100, ensuring that each of the plurality of second light-emitting units 4 in the second light-emitting layer of the display panel 100 may function properly, thereby avoiding the problem of abnormal second light-emitting units 4 being unable to emit a light during the manufacturing process of the display panel 100, and improving the yield and display performance of the display panel 100. After the re-transfer new second light-emitting element 41 to repair the abnormal light-emitting unit is completed, the second encapsulation layer 7 is further manufactured on the side of the second light-emitting unit 4 away from the driving substrate 1, so as to encapsulate and protect the plurality of second light-emitting units 4, and thereby form the structure of the display panel 100 as shown in FIG. 1.

Furthermore, in the subsequent use of the display panel 100 that is formed, in a case where an abnormality occurs in the second light-emitting unit 4, the repair method in original operation S4 may still be used to repair the display panel 100, that is, by removing the light-emitting element of the abnormal light-emitting unit, electrically connecting the first light-emitting unit 3 corresponding to the abnormal light-emitting unit to both the first voltage line L1 and the second voltage line L2, and using the first light-emitting unit 3 to replace the abnormal light-emitting unit for light emission, thereby realizing the repair of the abnormal light-emitting unit.

In some embodiments, operation S3 may also not include the manufacturing the second encapsulation layer 7 on the side of the plurality of second light-emitting elements 41 away from the driving substrate 1 as described in operation S33. The detecting whether there is an abnormal light-emitting unit among the plurality of second light-emitting units 4 may be performed in operation S4. After repairing the abnormal light-emitting unit, removing the light-emitting element of the abnormal light-emitting unit, and electrically connecting the first light-emitting unit 3 corresponding to the abnormal light-emitting unit to the first voltage line L1 and the second voltage line L2, the second encapsulation layer 7 may be manufactured on the side of the second light-emitting element 41 away from the driving substrate 1. That is, the plurality of second light-emitting units 4 may be inspected and repaired before manufacturing the second encapsulation layer 7 during the manufacturing process of the display panel 100. The first light-emitting unit 3 corresponding to the abnormal light-emitting unit may be directly configured to replace the abnormal light-emitting unit for light emission, thus avoiding the issue of the second light-emitting unit 4 being unable to emit a light normally during the manufacturing process of the display panel 100, and improving the performance of the formed display panel 100. In some embodiments, the structure of the display panel 100 as shown in FIG. 2 may be directly obtained during the manufacturing process.

By using the method for manufacturing the display panel 100 provided in the embodiments of the present disclosure, display panel 100 that is manufactured may achieve repair of abnormal light-emitting units without affecting the resolution of the display panel 100. The display panel 100 also has good visual quality and may effectively solve the problem in the related art in which bad point repair of a Micro LED display panel 100 is difficult to achieve.

The above descriptions are merely embodiments of the present disclosure and are not intended to limit the scope of the present disclosure. Any equivalent structural or process changes made based on the content of the present specification and drawings, or direct or indirect applications in other related technical fields, are also intended to be included within the scope of protection of the present disclosure.

1. A display panel, comprising:
a driving substrate, comprising a first voltage line and a second voltage line; wherein one of the first voltage line and the second voltage line is a positive power voltage line, and an other is a ground voltage line; and
a plurality of stacked light-emitting unit modules arranged at intervals and arranged on a side of the driving substrate, each of the plurality of stacked light-emitting unit modules comprising a first light-emitting unit and a second light-emitting unit stacked and correspondingly arranged;
wherein the first light-emitting unit comprises a first light-emitting element, a first connection electrode, and a second connection electrode; the first connection electrode and the second connection electrode are arranged at intervals, the first light-emitting element is electrically connected to the first connection electrode and the second connection electrode, respectively; the first connection electrode and the second connection electrode correspond one-to-one with the first voltage line and the second voltage line but are not all electrically connected;
the second light-emitting unit is arranged on a side of the first light-emitting unit away from the driving substrate, the second light-emitting unit comprises a second light-emitting element, a third connection electrode, and a fourth connection electrode; the third connection electrode and the fourth connection electrode are arranged at intervals, the second light-emitting element is electrically connected to the third connection electrode and the fourth connection electrode, respectively; the third connection electrode and the fourth connection electrode are electrically connected to the first voltage line and the second voltage line in a one-to-one correspondence, and an orthographic projection of the first light-emitting element on the driving substrate at least partially overlaps with an orthographic projection of the second light-emitting element on the driving substrate.

2. The display panel according to claim 1, wherein the first connection electrode of the each of the plurality of stacked light-emitting unit modules is arranged corresponding to and electrically connected to the first voltage line, and the second connection electrode of the each of the plurality of stacked light-emitting unit modules is arranged corresponding to but not electrically connected to the second voltage line.

3. The display panel according to claim 2, further comprising:
an independent light-emitting unit module, arranged on the side of the driving substrate, the independent light-emitting unit module and the plurality of stacked light-emitting unit modules being arranged at intervals, the independent light-emitting unit module comprising the first light-emitting unit but not comprising the second light-emitting element;
wherein the first connection electrode and the second connection electrode of the independent light-emitting unit module are electrically connected to the first voltage line and the second voltage line in a one-to-one correspondence.

4. The display panel according to claim 3, wherein the independent light-emitting unit module further comprises:
a first encapsulation layer, covering the first light-emitting unit; and
the third connection electrode and the fourth connection electrode, arranged on a side of the first encapsulation layer away from the driving substrate, the third connection electrode and the fourth connection electrode of the independent light-emitting unit module being electrically connected to the first connection electrode and the second connection electrode in a one-to-one correspondence, the first connection electrode of the independent light-emitting unit module being directly arranged corresponding to and electrically connected to the first voltage line, and the second connection electrode of the independent light-emitting unit module being electrically connected to the second voltage line through the fourth connection electrode.

5. The display panel according to claim 1, wherein the orthographic projection of the second light-emitting element of the each of the plurality of stacked light-emitting unit modules on the driving substrate overlaps with the orthographic projection of the first light-emitting element of the plurality of stacked light-emitting unit modules on the driving substrate.

6. The display panel according to claim 5, wherein the second light-emitting element of the second light-emitting unit in the each of the plurality of stacked light-emitting unit modules and the first light-emitting element of the first light-emitting unit in the each of the plurality of stacked light-emitting unit modules have a same color.

7. The display panel according to claim 4, wherein a second encapsulation layer is further arranged on a side of the second light-emitting unit away from the first light-emitting unit, the second encapsulation layer covers the second light-emitting unit.

8. The display panel according to claim 4, wherein the first encapsulation layer is arranged on the side of the first light-emitting unit away from the driving substrate, and the second light-emitting unit is arranged on a side of the first encapsulation layer away from the first light-emitting unit.

9. The display panel according to claim 8, wherein a first via hole is defined at a position where the first encapsulation layer corresponds to the first connection electrode of the first light-emitting unit and the third connection electrode of the second light-emitting unit, the first via hole penetrates the first encapsulation layer and exposes a portion of the first connection electrode, the third connection electrode extends into the first via hole and is in contact with and electrically connected to the first connection electrode, the third connection electrode is electrically connected to the first voltage line through the first connection electrode, and the fourth connection electrode penetrates the first encapsulation layer and is directly connected to the second voltage line.

10. The display panel according to claim 9, wherein a second via hole is defined on the first encapsulation layer at the position corresponding to the fourth connection electrode and the second connection electrode of the independent light-emitting unit module, and the second via hole penetrates the first encapsulation layer.

11. The display panel according to claim 10, wherein the fourth connection electrode extends into the second via hole and is in contact with and electrically connected to the second connection electrode, or an electrical connection between the fourth connection electrode and the second connection electrode of the independent light-emitting unit module is established by conductive paste filled into the second via hole.

12. A method for manufacturing a display panel, comprising:
providing a driving substrate, the driving substrate comprising a first voltage line and a second voltage line; wherein one of the first voltage line and the second voltage line is a positive power voltage line, and the other is a ground voltage line;
manufacturing a first light-emitting layer on a side of the driving substrate, the first light-emitting layer comprising a plurality of first light-emitting units, each of the plurality of first light-emitting units comprising a first light-emitting element, a first connection electrode, and a second connection electrode; the first connection electrode and the second connection electrode being arranged at intervals, the first light-emitting element being electrically connected to the first connection electrode and the second connection electrode, respectively; wherein the first connection electrode and the second connection electrode correspond one-to-one with the first voltage line and the second voltage line but are not all electrically connected;
manufacturing a second light-emitting layer on a side of the first light-emitting layer away from the driving substrate, the second light-emitting layer comprising a plurality of second light-emitting units, the plurality of second light-emitting units corresponding one-to-one with the plurality of first light-emitting units, each of the plurality of second light-emitting unit comprising a second light-emitting element, a third connection electrode, and a fourth connection electrode; the third connection electrode and the fourth connection electrode being arranged at intervals, the second light-emitting element being electrically connected to the third connection electrode and the fourth connection electrode, respectively; wherein the third connection electrode and the fourth connection electrode are electrically connected to the first voltage line and the second voltage line in a one-to-one correspondence; and
detecting whether there is an abnormal light-emitting unit among the plurality of second light-emitting units; in a case where the abnormal light-emitting unit exists, removing the light-emitting element of the abnormal light-emitting unit and electrically connecting the first light-emitting unit corresponding to the abnormal light-emitting unit to the first voltage line and the second voltage line, such that the first connection electrode and the second connection electrode of the first light-emitting unit corresponding to the abnormal light-emitting unit are electrically connected to the first voltage line and the second voltage line in a one-to-one correspondence.

13. The method for manufacturing a display panel according to claim 12, wherein the manufacturing the first light-emitting layer on the side of the driving substrate comprises:
manufacturing a plurality of first electrode pairs arranged at intervals and arranged on the side of the driving substrate, each of the plurality of first electrode pairs comprising the first connection electrode and the second connection electrode, the first connection electrode being arranged corresponding to and electrically connected to the first voltage line, and the second connection electrode being arranged corresponding to but not electrically connected to the second voltage line;
transferring a plurality of first light-emitting elements on the side of the driving substrate, each of the plurality of first light-emitting elements comprising a first epitaxial layer, a first contact electrode, and a second contact electrode; the plurality of first light-emitting elements being arranged in a one-to-one correspondence with the plurality of first electrode pairs, and the first contact electrode and the second contact electrode being electrically connected to the first connection electrode and the second connection electrode in a one-to-one correspondence; and
manufacturing a first encapsulation layer on a side of the plurality of first light-emitting elements away from the driving substrate, and defining a first via hole on the first encapsulation layer, the first via hole penetrating the first encapsulation layer and exposing the first connection electrode.

14. The method for manufacturing a display panel according to claim 13, wherein the manufacturing the second light-emitting layer on the side of the first light-emitting layer away from the driving substrate comprises:
manufacturing a plurality of second electrode pairs arranged at intervals and arranged on a side of the first encapsulation layer away from the driving substrate, each of the plurality of second electrode pairs comprising the third connection electrode and the fourth connection electrode, the third connection electrode being electrically connected to the first connection electrode through the first via hole, an orthographic projection of the fourth connection electrode on the driving substrate partially overlapping with an orthographic projection of the second connection electrode on the driving substrate to form an overlapping region;
transferring a plurality of the second light-emitting elements on the side of the first encapsulation layer away from the driving substrate, each of the plurality of second light-emitting element comprising a second epitaxial layer, a third contact electrode, and a fourth contact electrode; the plurality of second light-emitting elements being arranged in a one-to-one correspondence with the plurality of second electrode pairs, and the third contact electrode and the fourth contact electrode being electrically connected to the third connection electrode and the fourth connection electrode in a one-to-one correspondence; and
manufacturing a second encapsulation layer on a side of the plurality of second light-emitting elements away from the driving substrate.

15. The method for manufacturing a display panel according to claim 14, wherein the removing the light-emitting element of the abnormal light-emitting unit and electrically connecting the first light-emitting unit corresponding to the abnormal light-emitting unit to the first voltage line and the second voltage line comprises:
removing the light-emitting element of the abnormal light-emitting unit and retaining the fourth connection electrode of the abnormal light-emitting unit;
defining a second via hole on the first encapsulation layer corresponding to the overlapping region, the second via hole penetrating the first encapsulation layer and exposing the second connection electrode; and
electrically connecting the fourth connection electrode to the second connection electrode through the second via hole.

16. The method for manufacturing a display panel according to claim 15, wherein the removing the light-emitting element of the abnormal light-emitting unit, comprises:
removing a portion of the second encapsulation layer corresponding to the abnormal light-emitting unit.

17. The method for manufacturing a display panel according to claim 16, wherein after electrically connecting the fourth connection electrode to the second connection electrode through the second via hole, the method further comprises:
filling a position of a removed light-emitting element of the abnormal light-emitting unit and the portion of the second encapsulation layer that is removed with encapsulant.

18. The method for manufacturing a display panel according to claim 12, wherein in a case where there is an abnormal light-emitting unit among the second light-emitting units, the method further comprises:
removing a light-emitting element of the abnormal light-emitting unit; and
transferring a new second light-emitting element at a position of the light-emitting element that is removed.

19. The method for manufacturing a display panel according to claim 18, wherein after transferring the new second light-emitting element at the position of the light-emitting element that is removed, the method further comprises:
manufacturing a second encapsulation layer on a side of the plurality of second light-emitting units away from the driving substrate.

20. The method for manufacturing a display panel according to claim 12, wherein orthographic projections of the plurality of second light-emitting elements on the driving substrate overlap with orthographic projections of the plurality of first light-emitting elements on the driving substrate.
